(19) United States
(12) Patent Application Publication
(10) Pub. No.: US 2010/0307589 A1
(43) Pub. Date: Dec. 9, 2010

(54) ORGANIC SOLAR CELL AND METHOD OF FABRICATING THE SAME

(75) Inventors: Jae-Young CHOI, Suwon-si (KR); Woong CHOI, Seongnam-si (KR); Soo-Ghang IHN, Hwaseong-si (KR)

Correspondence Address: CANTOR COLBURN LLP, 20 Church Street, 22nd Floor, Hartford, CT, 06103, US

(73) Assignee: SAMSUNG ELECTRONICS CO., LTD., Suwon-si (KR)

(21) Appl. No.: 12/693,746

(22) Filed: Jan. 26, 2010

(30) Foreign Application Priority Data
Jun. 3, 2009 (KR) 10-2009-0049248

(51) Int. Cl. H01L 51/44; H01L 51/48

(52) U.S. Cl. 136/261; 438/82; 257/E51.012

(57) ABSTRACT

An organic solar cell includes; a cathode, an anode disposed substantially opposite the cathode, a photoactive layer disposed between the cathode and the anode, wherein the photoactive layer includes an electron donor, an electron acceptor, and a nanostructure, and wherein the nanostructure includes an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

### CROSS-REFERENCE TO RELATED APPLICATION

This application claims priority to Korean Patent Application No. 10-2009-0049248, filed on Jun. 3, 2009, and all the benefits accruing therefrom under 35 U.S.C. §119, the content of which in its entirety is herein incorporated by reference.

### BACKGROUND

1. Field

This disclosure relates to an organic solar cell and a method of fabricating the same.

2. Description of the Related Art

A solar cell generally refers to a photoelectric conversion device that transforms solar energy into electrical energy, and solar cell technology has garnered much attention as a potentially infinite, i.e., renewable, pollution-free next generation energy resource.

In general, solar cells may be classified into different types, such as inorganic solar cells or organic solar cells depending on a material forming a thin film of the solar cell. Since the organic solar cell typically includes various organic semiconductor materials in a small amount, it may have a decreased cost compared to an inorganic solar cell. In addition, since various organic semiconductor materials are made into a thin film fabricated in a solution process, the organic solar cell device may be fabricated in a simple method.

In general, an organic solar cell is further classified as a bi-layer p-n junction organic solar cell that includes a photoactive layer including two layers such as a p-type semiconductor thin film and an n-type semiconductor thin film, or a bulk hetero-junction (“BHJ”) organic solar cell that includes a photoactive layer including an n-type semiconductor and a p-type semiconductor blended together, depending on the structure of the photoactive layer.

A typical bi-layer p-n junction-type organic solar cell is shown in FIG. 6. Referring to FIG. 6, an organic solar cell 100 includes a substrate 101, an indium tin oxide (“ITO”) anode 103, a photoactive layer 111, and a cathode 105. The photoactive layer 111 includes a p-type semiconductor thin film 107 and an n-type semiconductor thin film 109. Excitons 117, including paired electrons 113 and holes 115, are formed within the p-type semiconductor thin film 107. The excitons 117 are separated into individual electrons 113 and holes 115 at a p-n junction part. The separated electrons 113 and holes 115 respectively move towards the n-type semiconductor thin film 109 and the p-type semiconductor thin film 107 from the p-n junction part, and are respectively absorbed at the cathode 105 and the anode 103 such that they may be externally used as electrical energy.

On the other hand, research has been conducted to create a solar cell having as high efficiency as possible to produce as much electrical energy from the sun as possible. In order to increase the efficiency of a solar cell, the number of excitons produced may be as large as possible, and a resultant charge may be withdrawn with minimal loss of charge.

A significant amount of the charge is a lot lost due to recombination of the produced electrons and holes within the photoactive layer 111 or within other layers of the organic solar cell 100. Accordingly, various methods of transferring the produced electrons and holes to an electrode with minimal loss have been suggested. However, they generally require an additional manufacturing process and thereby increase the manufacturing cost.

### SUMMARY

One aspect of this disclosure provides an organic solar cell having an increased amount of photocurrent and improved photoelectric conversion efficiency by improving a moving path of electrons in a photoactive layer.

Another aspect of this disclosure provides a method of fabricating an organic solar cell with high efficiency in a simple method and with a low cost.

According to one aspect of this disclosure, an embodiment of an organic solar cell includes; a cathode, an anode disposed substantially opposite the cathode, and a photoactive layer disposed between the cathode and the anode, wherein the photoactive layer includes an electron donor, an electron acceptor and a nanostructure, and wherein the nanostructure includes an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

In one embodiment, the nanostructure may be physically or electrically connected to the cathode.

In one embodiment, the semiconductor element, semiconductor compound or semiconductor carbon material may satisfy the following Equation 1 and Equation 2:

[Equation 1]

|LUMO_{A}|≦|CBE_{N}|

[Equation 2]

|HOMO_{D}|<|VBE_{N}|

wherein in Equation 1, LUMO_{A} refers to an energy level of a lowest unoccupied molecular orbital (“LUMO”) of the electron acceptor and CBE_{N} refers to a conduction band edge (“CBE”) of the nanostructure, while in Equation 2, HOMO_{D} refers to an energy level of a highest occupied molecular orbital (“HOMO”) of the electron donor and VBE_{N} refers to a valance band edge (“VBE”) of a nanostructure.

In one embodiment, the nanostructure may be surface-treated with a hole blocking material that may be represented by the following Equation 3 and Equation 4:

[Equation 3]

|LUMO_{A}|≦(|CBE_{HBL}| or |LUMO_{HBL}|)

[Equation 4]

|HOMO_{D}|<(|VBE_{HBL}| or |HOMO_{HBL}|)

wherein in Equation 3, LUMO_{A} refers to an erergy level of a LUMO of the electron acceptor, CBE_{HBL} refers to a CBE of the hole blocking material, and LUMO_{HBL} refers to an energy level of a LUMO of the hole blocking material, while in Equation 4, HOMO_{D} refers to an energy level of a HOMO of the electron donor, VBE_{N} refers to a VBE of the hole blocking material and HOMO_{HBL} refers to an energy level of a HOMO of the hole blocking material.

In one embodiment, the semiconductor element may include silicon (Si), germanium (Ge), or a combination thereof. In one embodiment, the semiconductor compound may include a group II-VI compound, a group III-V compound, a group IV-VI compound, a group IV compound, a semiconductor metal oxide or a combination thereof.

In one embodiment, the semiconductor carbon material and metallic carbon material which is surface-treated with a hole blocking material may include at least one selected from the group consisting of carbon nanotubes, graphene and a combination thereof.

In one embodiment, the metal may include one selected from the group consisting of silver, gold, indium, nickel, copper, aluminum, titanium, platinum, tungsten, iron, mixtures thereof and alloys thereof.

In one embodiment, the hole blocking material may include one selected from the group consisting of fullerene, a fullerene derivative, bathocuproine (“BCP”), a semiconductor element, a semiconductor compound and a combination thereof.

In one embodiment, the nanostructure may have a substantially one-dimensional linear structure, a substantially two-dimensional flat structure, or a three-dimensional cubic structure. In one embodiment the nanostructure may be selected from the group consisting of nanotubes, nanorods, nanowire, nanotrees, nanotetrapods, nanodisks, nanoplates, nanoribbons and a combination thereof.

In one embodiment, the nanostructure may include a self-assembled monolayer (“SAM”) including a hole blocking material on a surface thereof, or may be treated to have a surface roughness or a hydrophilic surface.

In one embodiment, the nanostructure may be included in an amount of about 0.1% to about 50% of an entire volume of a photoactive layer.

In one embodiment, an electron blocking layer may be further disposed between the anode and photoactive layer.

According to another aspect, an embodiment of a method of fabricating an organic solar cell is provided that includes; providing a cathode on a substrate, providing a photoactive layer by coating a mixed solution including a dispersed electron donor, electron acceptor, and nanostructure and a solvent on the cathode and providing an anode disposed substantially opposite the cathode.

According to a further aspect of this disclosure, a method of fabricating an organic solar cell is provided that includes; providing a cathode on a substrate, arranging a nanostructure to be substantially perpendicular to, and disposed on, the cathode, coating a mixed solution of an electron donor and an electron acceptor on the nanostructure to form a photoactive layer together with the nanostructure, and providing an anode on the photoactive layer.

In one embodiment, the nanostructure may be pretreated by at least one selected from the group consisting of disposing a SAM of a hole blocking material, forming a surface roughness by selective etching, and making the surface hydrophilic.

Other aspects of this disclosure will be described in the following detailed description.

### BRIEF DESCRIPTION OF THE DRAWINGS

The above and other aspects, advantages and features of this disclosure will become more apparent by describing in further detail exemplary embodiments thereof with reference to the accompanying drawings, in which:

FIG. 1 is a cross-sectional view of an embodiment of an organic solar cell;

FIG. 2 is a cross-sectional view of another embodiment of an organic solar cell;

FIG. 3 is a cross-sectional view of another embodiment of an organic solar cell;

FIG. 4 is a flow chart showing an embodiment of a fabricating process of an organic solar cell;

FIG. 5 is a flow chart showing another embodiment of a fabricating process of an organic solar cell; and

FIG. 6 schematically shows a structure of a bi-layer p-n junction organic solar cell.

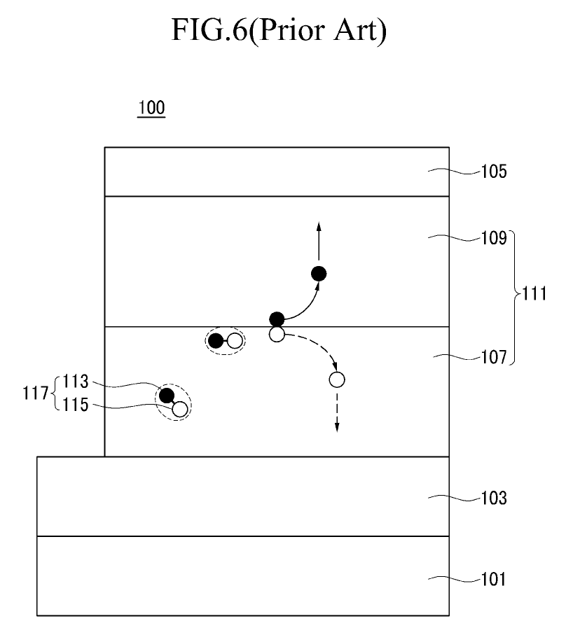

### DETAILED DESCRIPTION

This disclosure now will be described more fully hereinafter with reference to the accompanying drawings in which some, but not all, embodiments of the disclosure are shown. This disclosure may, however, be embodied in many different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present disclosure are described herein with reference to cross section illustrations that are schematic illustrations of idealized embodiments of the present disclosure. As such, variations from the shapes of the illustrations as a result, for example, of manufacturing techniques and/or tolerances, are to be expected. Thus, embodiments of the present disclosure should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present disclosure.

All methods described herein can be performed in a suitable order unless otherwise indicated herein or otherwise clearly contradicted by context. The use of any and all examples, or exemplary language (e.g., “such as”), is intended merely to better illustrate the disclosure and does not pose a limitation on the scope of the disclosure unless otherwise claimed. No language in the specification should be construed as indicating any non-claimed element as essential to the practice of the disclosure as used herein.

Hereinafter, the present disclosure will be described in detail with reference to the accompanying drawings.

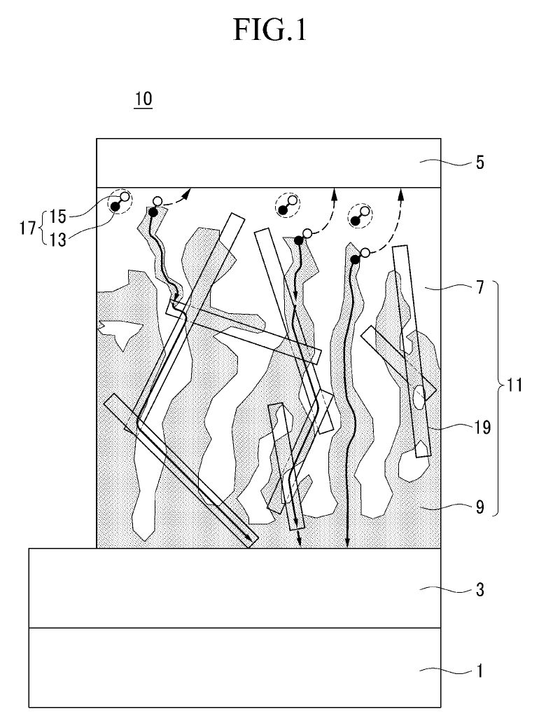

Hereinafter, referring to FIG. 1, an embodiment of an organic solar cell is described.

FIG. 1 is a cross-sectional view of one embodiment of an organic solar cell 10. The organic solar cell 10 includes a photoactive layer 11 between an anode 5 and a cathode 3 positioned on a substrate 1. FIG. 1 shows that the cathode 3 is positioned on the substrate 1 in the organic solar cell 10, but alternative embodiments include configurations wherein the anode 5 may be positioned on the substrate 1, e.g., the positional arrangement of the anode 5 and cathode 3 may be reversed.

The substrate 1 may be made of a transparent material, embodiments of which include glass, polycarbonate, polymethyl methacrylate, polyethylene terephthalate, polyimide, polyethersulfone (“PES”), and other materials with similar characteristics, without particular limitation.

Embodiments of the cathode 3 may include indium tin oxide (“ITO”), SnO₂, In₂O₃-ZnO (“IZO”), aluminum-doped ZnO (“AZO”), gallium-doped ZnO (“GZO”), and other materials with similar characteristics as a light-transmissible transparent electrode.

The anode 5 may be used without any limitation as long as it has a larger work function than that of the cathode 3, and may include a metal, a metal alloy, a semi-metal, a light-transmissible transparent oxide or other materials having similar characteristics. Embodiments of the metal may include an alkali metal such as lithium (Li), sodium (Na), combinations thereof and other materials having similar characteristics; an alkaline-earth metal such as beryllium (Be), magnesium (Mg), combinations thereof and other materials having similar characteristics; aluminum (Al); transition elements such as silver (Ag), gold (Au), cobalt (Co), iridium (Ir), nickel (Ni), osmium (Os), palladium (Pd), platinum (Pt), and other materials having similar characteristics; a rare earth element; a semi-metal such as selenium (Se), and other materials having similar characteristics. Embodiments of the metal alloy may include a sodium-potassium alloy, a magnesium-indium alloy, an aluminum-lithium alloy, combinations thereof and other materials having similar characteristics. In addition, embodiments of the anode 5 may include a laminate including a first layer formed of a metal or a metal alloy and a second layer formed of a metal oxide or halide. For example, in one embodiment the anode 5 may include an electrode such as MoO₃/Ag, Al₂O₃/Al, and other materials having similar characteristics. The light-transmissible transparent oxide may include ITO, SnO₂, IZO, AZO, GZO, and other materials having similar characteristics mentioned for the anode 5 material, and may have a larger work function than the cathode 3.

Alternatively, in embodiments wherein a buffer layer including a transition metal oxide such as MoO₃, V₂O₅, WO₃, and the like is further disposed between the anode 5 and the photoactive layer 11, the anode 5 material does not have to have the above work function requirement relative to the cathode 3. The transition metal oxide buffer layer may also act as a hole transport/electron blocking layer due to a relatively large band gap of the material therein, and provides band alignment.

The photoactive layer 11 may include an electron donor 7 and an electron acceptor 9 mixed together, and a nanostructure 19, which functions as an electron transporter. As illustrated in FIG. 1, the electron donor 7 and the electron acceptor 9 may be mixed to create interdigitated lobes and islands of material within the photo active layer 11.

The electron donor 7 may include a conductive polymer, a low molecular semiconductor, and other similar materials as a p-type semiconductor. Embodiments thereof may include polyaniline, polypyrrole, polythiophene, poly(p-phenylenevinylene), poly[2-methoxy-5-(2′-ethyl-hexyloxy)-1,4-phenylene vinylene (“MEH-PPV”), poly(2-methoxy-5-(3,7-dimethyloctyloxy)-1,4-phenylene-vinylene (“MDMO-PPV”), pentacene, poly(3,4-ethylenedioxythiophene) (“PEDOT”), poly(3-alkylthiophene), for example, poly(3-hexylthiophene) (“P3HT”), combinations thereof and other materials with similar characteristics.

The electron acceptor 9 may include fullerene with a large affinity to electrons (e.g., C60, C70, C74, C76, C78, C82, C84, C720, C860, and other materials with similar characteristics); fullerene derivatives such as 1-(3-methoxy-carbonyl)propyl-1-phenyl-(6,6)C61 (“PCBM”), C71-PCBM, C84-PCBM, bis-PCBM, combinations thereof and other materials with similar characteristics; perylene; an inorganic semiconductor such as CdS, CdTe, CdSe, ZnO, TiOx, Si, GaAs, InP, GaP, AlAs, and other materials with similar characteristics; or a mixture thereof.

The electron donor 7 and the electron acceptor 9 may be mixed in a weight ratio of about 1:9 to about 9:1. When they are mixed within the above described range, a photoactive layer 11 may be easily formed for improvement of photocurrent efficiency.

In operation, photo-excitement produces excitons 17 including a pair of an electron 13 and a hole 15 from both the electron donor 7 and the electron acceptor 5, respectively. As shown in FIG. 1 exciton formation occurs in the electron donor 7. Each exciton 17 is separated into the electron 13 and the hole 15 at the interface of the electron donor 7 and the electron acceptor 9 due to an affinity difference of the two materials. The separated electron 13 moves to the cathode 3 through the electron acceptor 9, and the hole 15 moves to the anode 5 through the electron donor 7 due to a built-in electric field. The electron 13 may hop across the electron acceptors 9 when it moves. Due to such a hopping process for electron transport, the electron 13 moves at a slow speed after the exciton decomposition and restricts the amount of photocurrent available for use, and therefore lowers the efficiency of the solar cell.

Therefore, the nanostructure 19 is included as an electron transporter in the photoactive layer 11, through which an electron 13 may move in order to increase speed of movement of the electron 13 separated from the exciton 17 toward the cathode 3. As a result, the electron 13 may be recombined with the hole 15 at a lower level, e.g., at the cathode 3, at a more rapid rate and therefore increase the amount of photocurrent available, improving photoelectric conversion efficiency. In addition, the nanostructure 19 may scatter light, increasing the light path in the photoactive layer 11, resultantly improving photoelectric conversion efficiency.

The nanostructure 19 may be physically and/or electrically connected to the cathode 3, or at least may reduce a travel time of an electron 13 across a distance towards the cathode 3. It also increases an electron-collecting area and electron-collecting efficiency, resultantly contributing to an increase in photoelectric conversion efficiency.

Embodiments of the nanostructure 19 may include an electron conductive material selected from the group consisting of a semiconductor element, a semiconductor compound, a semiconductor carbon material, a metallic carbon material that is surface-treated with a hole blocking material, a metal that is surface-treated with a hole blocking material, and a combination thereof.

When the semiconductor element, semiconductor compound, and semiconductor carbon material for the nanostructure 19 satisfies the following Equations 1 and 2, they do not need surface treatment due to their hole blocking properties.

[Equation 1]

|LUMO_{A}|≦|CBE_{N}|

[Equation 2]

|HOMO_{D}|<|VBE_{N}|

In Equation 1, LUMO_{A} refers to an energy level of a lowest unoccupied molecular orbital (“LUMO”) of the electron acceptor 9, and CBE_{N} refers to a conduction band edge (“CBE”) of the nanostructure 19. In Equation 2, HOMO_{D} refers to an energy level of a high-test occupied molecular orbital (“HOMO”) of the electron donor 7, and VBE_{N} refers to a valance band edge (“VBE”) of a nanostructure 19.

Embodiments of the semiconductor element may include one selected from the group consisting of silicon (Si), germanium (Ge), and combinations thereof, but is not limited thereto.

Embodiments of the semiconductor compound may include a group II-VI compound, a group III-V compound, a group IV-VI compound, a group IV compound, a semiconductor metal oxide, or a combination thereof. Embodiments of the group II-VI compound may be selected from the group consisting of a binary element compound such as CdSe, CdS, CdTe, ZnS, ZnSe, ZnTe, ZnO, HgS, HgSe, HgTe, combinations thereof and other materials with similar characteristics, a ternary element compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, combinations thereof and other materials with similar characteristics, and a quaternary element compound such as HgZnSTe, CdZnSeS, CdZnSeTe, CdZnSTe, CdHgSeS, CdHgSeTe, CdHgSTe, HgZnSeS, HgZnSeTe, HgZnSTe, combinations thereof and other materials with similar characteristics; the group III-V compound may be selected from the group consisting of a binary element compound such as GaN, GaP, GaAs, GaSb, AlN, AlP, AlAs, AlSb, InN, InP, InAs, InSb, combinations thereof and other materials with similar characteristics, a ternary element compound such as AlGaAs, AlGaP, AlGaN, InGaAs, InGaP, InGaN, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, combinations thereof and other materials with similar characteristics, and a quaternary element compound such as InAlGaAs, InAlGaP, InAlGaN, GaAlNAs, GaAlNSb, GaAlPAs, GaAlPSb, GalnNP, GalnNAs, GalnNSb, GalnPAs, GalnPSb, InAlNP, InAlNAs, InAlNSb, InAlPAs, InAlPSb, combinations thereof and other materials with similar characteristics; the group IV-VI compound may be selected from the group consisting of a binary element compound such as SnS, SnSe, SnTe, PbS, PbSe, PbTe, combinations thereof and other materials with similar characteristics, a ternary element compound such as SnSeS, SnSeTe, SnSTe, PbSeS, PbSeTe, PbSTe, SnPbS, SnPbSe, SnPbTe, combinations thereof and other materials with similar characteristics, and a quaternary element compound such as SnPbSSe, SnPbSeTe, SnPbSTe, combinations thereof and other materials with similar characteristics; the group IV compound may be selected from the group consisting of a binary element compound such as SiC, SiGe, combinations thereof and other materials with similar characteristics; and the semiconductive metal oxide may be selected from the group consisting of indium oxide (In₂O₃), zinc oxide (ZnO), titanium oxide, tin oxide (SnO₂), combinations thereof and other materials with similar characteristics.

Embodiments of the semiconductor carbon material may include one selected from the group consisting of carbon nanotubes, graphene, and combinations thereof, other materials with similar characteristics but is not limited thereto.

When the semiconductor element, the semiconductor compound, or the semiconductor carbon material is not represented by the above Equations 1 and 2, they may be surface-treated with a hole blocking material represented by the following Equations 3 and 4.

[Equation 3]

LUMO_{A}|≦(|CBE_{HBL}| or |LUMO_{HBL}|)

[Equation 4]

|HOMO_{D}|<(|VBE_{HBL} | or |HOMO_{HBL}|)

In Equation 3, LUMO_{A} refers to an energy level of a LUMO of the electron acceptor 9, CBE_{HBL} refers to a CBE of the hole blocking material, and LUMO_{HBL} refers to an energy level of a LUMO of the hole blocking material, and in Equation 4, HOMO_{D} refers to an energy level of a HOMO of the electron donor 7, VBE_{N} refers to a VBE of the hole blocking material, and HOMO_{HBL} refers to an energy level of a HOMO of the hole blocking material.

The hole blocking material may be selected from the group consisting of fullerene (C60, C70, C74, C76, C78, C82, C84, C720, C860, and other materials with similar characteristics); fullerene derivatives such as PCBM, C71-PCBM, C84-PCBM, bis-PCBM, and the like; bathocuproine (“BCP”); a semiconductor element; and a semiconductor compound.

Embodiments of the semiconductor element and the semiconductor compound may be the same as the aforementioned semiconductor element and a semiconductor compound in the nanostructure 19.

The hole blocking material may be coated on a surface of a nanostructure 19 in a dry process such as chemical vapor deposition (“CVD”) or in a solution process such as spray coating, spin coating, or dipping coating or other suitable methods. These coating methods may be appropriately selected depending on the hole blocking material. In addition, the hole blocking material may be surface-treated with a self-assembled monolayer (“SAM”) on the surface of the nanostructure 19.

The carbon material may be semi-conductive or metallic depending on the manufacturing process thereof. When the nanostructure 19 includes a metallic carbon material, its surface is treated with a hole blocking material so that it may selectively accept electrons.

Embodiments of the metallic carbon material may be selected from the group consisting of carbon nanotubes, graphene, a combination thereof and other materials having similar characteristics.

The metal may have no particular limit, as long as it is a conductive metal, and for example embodiments thereof may be selected from the group consisting of a metal such as silver, gold, indium, nickel, copper, aluminum, titanium, platinum, tungsten, iron, and other materials having similar characteristics, a mixture thereof, and an alloy thereof.

When the nanostructure 19 includes the metallic carbon material or a metal, its surface is treated with a hole blocking material so that it may selectively accept electrons.

The hole blocking material for surface-treating the metal or the metallic carbon material may include a material satisfying Equations 3 and 4. Examples thereof and surface treatment methods are substantially the same as described above.

The nanostructure 19 may have a one-dimensional linear structure, a two-dimensional flat structure, or a three-dimensional cubic structure. The one-dimensional linear structure refers to a nanostructure having a thickness that may be ignored compared with the length, e.g., its thickness is at least an order of magnitude smaller than its length. The two-dimensional flat structure has a thickness that may be ignored compared with the area, e.g., its thickness is at least an order of magnitude smaller than its area. This nanostructure 19 may have various shapes such as nanotube, nanorod, nanowire, nanotree, nanotetrapod, nanodisk, nanoplate, nanoribbon, and the like. In addition, nanostructures 19 of different shapes may be mixed.

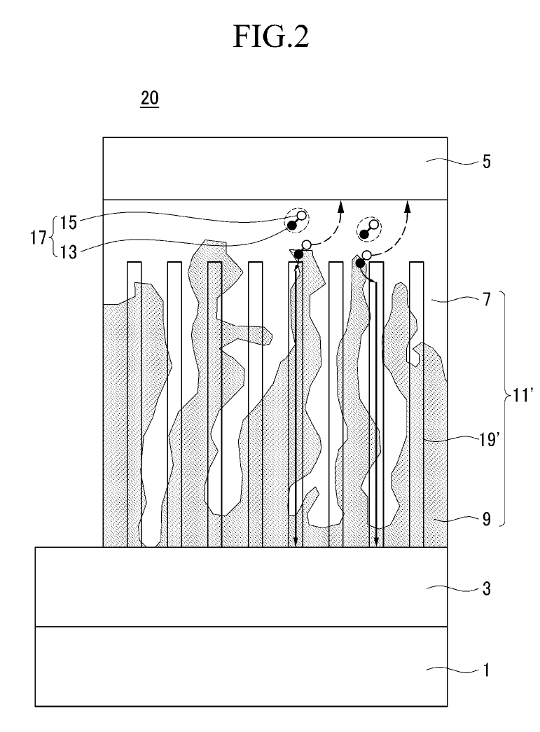

As shown in FIG. 2, a nanostructure 19′ included in a photoactive layer 11′ of an organic solar cell 20 may be arranged in a direction substantially normal to a surface of the cathode 3, e.g., the nanostructures 19′ are substantially perpendicular to the cathode 3. Herein, the nanosturctures form about a 90° with respect to the cathode 3. Therefore, in one embodiment, the nanostructure 19′ may be arranged in a substantially vertical direction. When the nanostructure 19′ is arranged as aforementioned, it may minimize the path for electrons 13 to travel to the cathode 3 and increase the amount of current available in the solar cell 20. In addition, one end of the nanostructure 19′ is physically/electrically connected to the cathode 3, and thereby an area for collecting electrons is increased as is collection efficiency of the electrons, contributing to increasing photoelectric conversion efficiency. In FIG. 2, the self-assembly monolayer (“SAM”) of the electron acceptor 9 is formed across a surface of the cathode 3, excluding locations wherein the cathode 3 contacts the nanostructure 19′. In addition, when a hole blocking layer (not shown) is inserted between the cathode 3 and the photoactive layer 11′, it may improve electron collection efficiency and prevent recombination of electrons and holes at the junction surface of an electron donor 7 and the cathode 3.

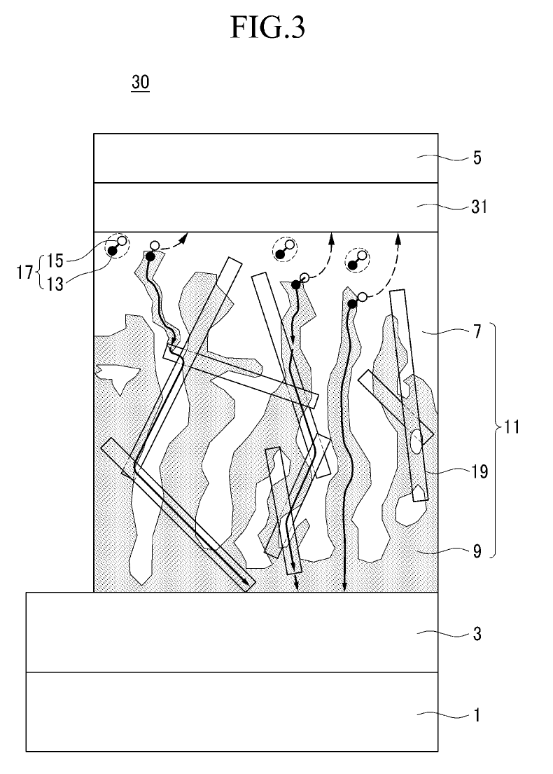

As shown in FIG. 3, an organic solar cell 30 further includes an electron blocking layer 31 between the anode 5 and the photoactive layer 11. The electron blocking layer 31 may prevent a short circuit that might occur if the electron conductive nanostructure 19 on the photoactive layer 11 were to directly contact the anode 5. This electron blocking layer 31 may include a transition metal oxide such as MoO₃, V₂O₅, WO₃, combinations thereof and other materials with similar characteristics; a conductive polymer such as PEDOT:PSS, polyaniline, polypyrrole, poly(p-phenylenevinylene), MEH-PPV, MDMO-PPV, poly(3-alkylthiophene), polythiophene, and other materials with similar characteristics; pentacene; CuPc; or a low molecular organic material such as a triphenyldiamine derivative (“TPD”), and other materials with similar characteristics.

The nanostructures 19 and 19′ may have a thickness ranging from about 0.8 nm to about 200 nm and a length ranging from about 100 nm to about 10 μm. In addition, the nanostructures 19 and 19′ may have an aspect ratio ranging from about 2 to about 2000. The aspect ratio indicates a length/thickness ratio when the nanostructure has a one-dimensional linear structure or a two-dimensional flat structure. When the nanostructures 19 and 19′ have a three-dimensional cubic structure, the aspect ratio indicates a length/thickness ratio of the one-dimensional linear or two-dimensional flat structure. When the nanostructures 19 and 19′ have a thickness, a length, and an aspect ratio within the above described range, they may transport and collect electrons effectively, and may thereby improve photoelectric conversion efficiency.

In addition, the nanostructures 19 and 19′ may be selectively etched to have surface roughness on their surface to increase their surface area and expand the contact area with the electron acceptor 9. Furthermore, embodiments include configurations wherein the nanostructures 19 and 19′ may be UV-treated or plasma-treated to make the surface hydrophilic. The surface treatment may be performed along with the surface treatment of the above-described hole blocking material.

The nanostructures 19 and 19′ may be included in an amount of about 0.1% to about 50% of the volume of the entire photoactive layers 11 and 11′. When the nanostructures 19 and 19′ are included within the above described range, they may improve mobility of the produced electron 13, improving photoelectric conversion efficiency.

The photoactive layers 11 and 11′ may be formed in a thickness ranging from about 100 nm to about 500 nm in terms of improving photoelectric conversion efficiency.

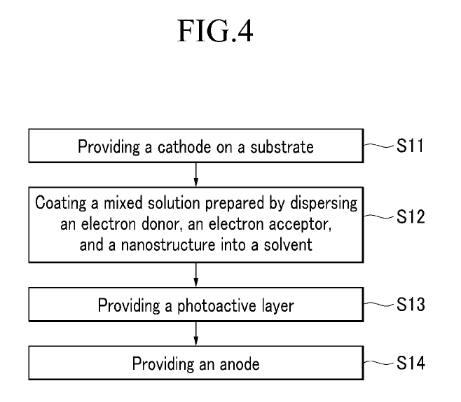

Hereinafter, referring to FIG. 4, a method of fabricating organic solar cells 10 and 30 having the aforementioned structure is illustrated.

First of all, a cathode 3 is positioned on a substrate 1 (S11). Then, a mixed solution prepared by dispersing an electron donor 7, an electron acceptor 9, and a nanostructure 19 in a solvent is coated thereon (S12). Herein, an electron blocking layer 31 may be positioned on the cathode 3 to prevent an electric short circuit as illustrated in FIG. 3.

The coating method of the mixed solution prepared by dispersing an electron donor 7, an electron acceptor 9, and a nanostructure 19 in a solvent may be selected from the group consisting of spray coating, dipping, reverse rolling, direct rolling, screen printing, spin coating, coating with a doctor blade, gravure coating, painting, slot die coating and various other similar methods depending on its viscosity, but the coating method is not limited thereto.

Since the nanostructure 19 is mixed with an electron donor 7 and an electron acceptor 9 and coated together, this method may contribute to simply fabricating organic solar cells 10 and 30 with high efficiency and low cost.

The nanostructure 19 may be treated on the surface with a hole-blocking material, selectively etched, or treated to make the surface hydrophilic in advance before being used for preparing the mixed solution.

Next, the solvent is removed after the coating to form a photoactive layer 11 (S13). Then, the anode 3 is positioned on the photoactive layer 11, or the electron blocking layer 31 as in the configuration illustrated in FIG. 3, completing organic solar cells 10 and 30 (S14). Herein, an electron blocking layer 31 may be further positioned on the photoactive layer 11 before providing the anode 5 to prevent an electric short circuit.

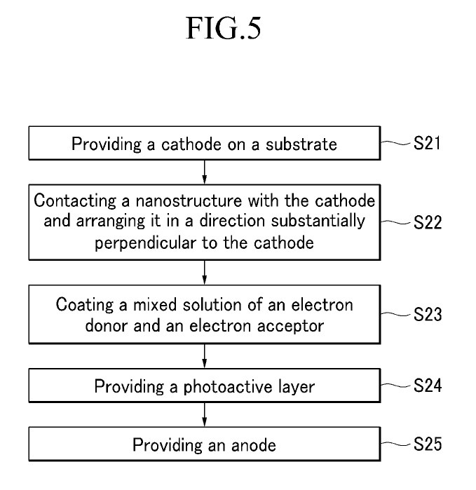

Referring to FIG. 5, a process of fabricating an organic solar cell 20 shown in FIG. 2 is illustrated. First of all, a cathode 3 is positioned on a substrate 1 (S21). Next, a nanostructure 19′ may be directly grown on the cathode 3 or etched from a complete layer, so that it may be arranged in a perpendicular direction to the cathode 3 (S22).

The nanostructure 19′ may be surface-treated with a hole-blocking material, selectively etched or treated to make the surface hydrophilic. Then, the mixed solution of an electron donor 7 and an electron acceptor 9 is coated on the nanostructure 19′ positioned on the cathode 3 (S23). The coating process may be performed in any of the above-described methods. Then, the solvent is removed to form a photoactive layer 11′ (S24). An anode 5 is positioned on the photoactive layer 11′, thereby completing an organic solar cell 30 (S25). Although not shown in FIG. 2, embodiments include configurations wherein an electron-blocking layer may be further formed on the photoactive layer 11′ before providing an anode 5 to prevent an electric short circuit, similar to the embodiment illustrated in FIG. 3.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An organic solar cell comprising:
a cathode;
an anode disposed substantially opposite the cathode; and
a photoactive layer disposed between the cathode and the anode,
wherein the photoactive layer comprises an electron donor, an electron acceptor and a nanostructure, and
wherein the nanostructure comprises an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

2. The organic solar cell of claim 1, wherein the nanostructure is at least one of physically and electrically connected to a cathode.

3. The organic solar cell of claim 1, wherein at least one of the semiconductor element, the semiconductor compound and the semiconductor carbon material satisfies Equation 1 and Equation 2:
[Equation 1]

|LUMO_{A}|≦|CBE_{N}|

[Equation 2]

|HOMO_{D}|<|VBE_{N} |

wherein, in Equation 1, LUMO_{A} refers to an energy level of a lowest unoccupied molecular orbital of the electron acceptor and CBE_{N} refers to a conduction band edge of the nanostructure, and
wherein, in Equation 2, HOMO_{D} refers to an energy level of a highest occupied molecular orbital of the electron donor and VBE_{N} refers to a valance band edge of a nanostructure.

4. The organic solar cell of claim 1, wherein the hole blocking material satisfies the following Equation 3 and Equation 4:
[Equation 3]

|LUMO_{A}|(|CBE_{HBL} | or |LUMO_{HBL}|)
[Equation 4]

|HOMO_{D}|(|VBE_{HBL}| or |HOMO_{HBL}I)
wherein, in Equation 3, LUMO_{A} refers to an energy level of a lowest unoccupied molecular orbital of the electron acceptor, CBE_{HBL} refers to a conduction band edge of the hole blocking material, and LUMO_{HBL} refers to an energy level of a lowest unoccupied molecular orbital of the hole blocking material, and
wherein, in Equation 4, HOMO_{D} refers to an energy level of a highest occupied molecular orbital of the electron donor, VBE_{N} refers to a valance Band Edge of the hole blocking material and HOMO_{HBL} refers to an energy level of a highest occupied molecular orbital of the hole blocking material.

5. The organic solar cell of claim 1, wherein at least one of the semiconductor element, the semiconductor compound and the semiconductor carbon material is surface-treated with a hole blocking material represented by Equation 3 and Equation 4:
[Equation 3]

|LUMO_{A}|≦(|CBE_{HBL}| or |LUMO_{HBL}|)
[Equation 4]

|HOMO_{D}|<(|VBE_{HBL}| or |HOMO_{HBL}I)
wherein, in Equation 3, LUMO_{A} refers to an energy level of a lowest unoccupied molecular orbital of the electron acceptor, CBE_{HBL} refers to a conduction band edge of the hole blocking material, and LUMO_{HBL} refers to an energy level of a lowest unoccupied molecular orbital of the hole blocking material, and
wherein, in Equation 4, HOMO_{D} refers to an energy level of a highest occupied molecular orbital of the electron donor, VBE_{N} refers to a valance band edge of the hole blocking material and HOMO_{HBL} refers to an energy level of a highest occupied molecular orbital of the hole blocking material.

6. The organic solar cell of claim 1, wherein the semiconductor element is selected from the group consisting of silicon (Si), germanium (Ge) and a combination thereof.

7. The organic solar cell of claim 1, wherein the semiconductor compound is selected from the group consisting of a group II-VI compound, a group III-V compound, a group IV-VI compound, a group IV compound, a semiconductor metal oxide and a combination thereof.

8. The organic solar cell of claim 1, wherein the semiconductor carbon material and the metallic carbon material which is surface-treated with the hole blocking material is selected from the group consisting of carbon nanotubes, graphene and a combination thereof.

9. The organic solar cell of claim 1, wherein the hole blocking material is selected from the group consisting of fullerene, a fullerene derivative, bathocuproine, a semiconductor element, a semiconductor compound and a combination thereof.

10. The organic solar cell of claim 1, wherein the nanostructure has a substantially one-dimensional linear structure, a substantially two-dimensional flat structure or a three-dimensional cubic structure.

11. The organic solar cell of claim 1, wherein the nanostructure is selected from the group consisting of nanotubes, nanorods, nanowire, nanotrees, nanotetrapods, nanodisks, nanoplates, nanoribbons and a combination thereof.

12. The organic solar cell of claim 1, wherein the nanostructure comprises a self-assembled monolayer of the hole blocking material on a surface thereof.

13. The organic solar cell of claim 1, wherein the nanostructure has surface roughness or is treated to be hydrophilic.

14. The organic solar cell of claim 1, wherein the nanostructure comprises about 0.1% to about 50% of an entire volume of the photoactive layer.

15. The organic solar cell of claim 1, wherein an electron blocking layer is positioned between the anode and the photoactive layer.

16. A method of fabricating the organic solar cell, the method comprising:
providing a cathode on a substrate;
providing a photoactive layer by coating a mixed solution including a dispersed electron donor, electron acceptor and nanostructure and a solvent on the cathode; and
providing an anode disposed substantially opposite the cathode,
wherein the nanostructure comprises an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

17. The method of claim 16, further comprising:
providing an electron blocking layer between the photoactive layer and the anode.

18. The method of claim 16, wherein the nanostructure is treated by at least one pretreatment process selected from the group consisting of disposing a self-assembled monolayer of a hole blocking material on a surface of the nanostructure, selective etching the surface of the nanostructure to provide surface roughness and applying a hydrophilic surface treatment to the nanostructure.

19. The method of claim 16, wherein the semiconductor element, the semiconductor compound or the semiconductor carbon material satisfies the following Equation 1 and Equation 2:
[Equation 1]

|LUMO_{A}|≦|CBE_{N}|

[Equation 2]

|HOMO_{D}|<|VBE_{N}|

wherein, in Equation 1, LUMO_{A} refers to an energy level of a lowest unoccupied molecular orbital of the electron acceptor and CBE_{N} refers to a conduction band edge of the nanostructure, and in Equation 2, HOMO_{D} refers to an energy level of a highest occupied molecular orbital of the electron donor and VBE_{N} refers to a valance band edge of a nanostructure.

20. The method of claim 16, wherein the hole blocking material satisfies the following Equation 3 and Equation 4:
[Equation 3]

|LUMO_{A}|≦(|CBE_{HBL}| or |LUMO_{HBL}|)
[Equation 4]

|HOMO_{D}|<(|VBE_{HBL}| or |HOMO_{HBL}|)
wherein, in Equation 3, LUMO_{A} refers to an energy level of a lowest unoccupied molecular orbital of the electron acceptor, CBE_{HBL} refers to a conduction band edge of the hole blocking material, and LUMO_{HBL} refers to an energy level of a lowest unoccupied molecular orbital of the hole blocking material, and in Equation 4, HOMO_{D} refers to an energy level of a highest occupied molecular orbital of the electron donor, VBE_{N} refers to a valance band edge of the hole blocking material and HOMO_{HBL} refers to an energy level of a highest occupied molecular orbital of the hole blocking material.

21. A method of fabricating an organic solar cell, the method comprising:
providing a cathode on a substrate;
arranging a nanostructure to be substantially perpendicular to, and disposed on, the cathode;
coating a mixed solution of an electron donor and an electron acceptor on the nanostructure to form a photoactive layer together with the nanostructure; and
providing an anode on the photoactive layer,
wherein the nanostructure comprises an electron conductive material selected from the group consisting of a semiconductor element, a semiconductor compound, a semiconductor carbon material, a metallic carbon material which is surface-treated with a hole blocking material, a metal which is surface-treated with a hole blocking material and a combination thereof.

22. The method of claim 21, further comprising providing an electron blocking layer between the photoactive layer and the anode.

23. The method of claim 21, wherein the nanostructure is treated by at least one pretreatment process selected from the group consisting of disposing a self-assembled monolayer of a hole blocking material on a surface of the nanostructure, selectively etching the nanostructure to provide surface roughness and hydrophilicly treating the surface of the nanostructure.

24. The method of claim 21, wherein the semiconductor element, the semiconductor compound or the semiconductor carbon material satisfies the following Equation 1 and Equation 2:
[Equation 1]

|LUMO_{A}|≦|CBE_{N}|

[Equation 2]

|HOMO_{D}|<|VBE_{N}|

wherein, in Equation 1, LUMO_{A} refers to an energy level of a lowest unoccupied molecular orbital of the electron acceptor and CBE_{N} refers to a conduction band edge of the nanostructure, and in Equation 2, HOMO_{D} refers to an energy level of a highest occupied molecular orbital of the electron donor and VBE_{N} refers to a valance band edge of a nanostructure.

25. The method of claim 21, wherein the hole blocking material satisfies the following Equation 3 and Equation 4:
[Equation 3]

|LUMO_{A}|≦(|CBE_{HBL| or |LUMO}_{HBL}|)
[Equation 4]

|HOMO_{D}|<(|VBE_{HBL}| or |HOMO_{HBL}|)
wherein, in Equation 3, LUMO_{A} refers to an energy level of a lowest unoccupied molecular orbital of the electron acceptor, CBE_{HBL} refers to a conduction band edge of the hole blocking material, and LUMO_{HBL} refers to an energy level of a lowest unoccupied molecular orbital of the hole blocking material, and in Equation 4, HOMO_{D} refers to an energy level of a highest occupied molecular orbital of the electron donor, VBE_{N} refers to a valance band edge of the hole blocking material and HOMO_{HBL} refers to an energy level of a highest occupied molecular orbital of the hole blocking material.
